(19) United States
(12) Patent Application Publication
(10) Pub. No.: US 2026/0025122 A1
(43) Pub. Date: Jan. 22, 2026

(54) ELECTROMECHANICAL MICROSYSTEM IN THE FORM OF A PIEZOELECTRIC RESONANT MEMBRANE BASED ON AN ALPHA QUARTZ LAYER, AND PROCESS FOR THE MANUFACTURING THEREOF

(71) Applicants: Centre National de la Recherche Scientifique, Paris (FR); Universite De Montpellier, Montpellier (FR)

(72) Inventors: Adrien CARRETERO, Clapiers (FR); David SANCHEZ FUENTES, Montpellier (FR); Claire JOLLY, Montpellier (FR); Ricardo GARCIA, Clapiers (FR); Rudy DESGARCEAUX, Montpellier (FR)

(21) Appl. No.: 18/997,426

(22) PCT Filed: Jul. 20, 2023
(86) PCT No.: PCT/EP2023/070221

§ 371 Date: Jan. 21, 2025

(30) Foreign Application Priority Data
Jul. 21, 2022 (FR) FR2207509

(51) Int. Cl. H03H 9/17; H03H 3/02; H03H 9/19

(52) U.S. Cl. CPC H03H 9/174; H03H 3/02; H03H 9/19; H03H 2003/023

(57) ABSTRACT

The present invention relates to the creation of an electromechanical microsystem in the form of a piezoelectric resonant membrane comprising a piezoelectric epitaxial pseudo-substrate based on an epitaxial α-quartz layer on a silicon wafer, as well as to a process for manufacturing such a microsystem.

### TECHNICAL FIELD

The present invention generally relates to making of a microelectromechanical system in the form of a piezoelectric resonant membrane comprising a piezoelectric epitaxial pseudo-substrate based on an epitaxial quartz-α layer on a silicon wafer, as well as the method for manufacturing such a microsystem.

### PRIOR ART

Piezoelectric materials are at the core of numerous daily applications thanks to their intrinsic ability to generate electric charges under an applied mechanical stress or to induce a mechanical deformation from an electrical input. Such properties make them key elements of motion detectors and resonators present in many wireless network sensors, which are devices capable of gathering and transmitting environmental data in a standalone manner. Thus, in this context, piezoelectric materials could find multiple military, medical and environmental applications. Today, the monolithic integration of these materials in the silicon technology and the micromachining thereof to develop cost-efficient alternate processes with superior performances are among the points at the centre of the current technology.

In general, PZT (lead zirconate titanate PbZrTiO₃), ZnO (zinc oxide) and AlN (aluminium nitride) piezoelectric materials are integrated in the form of thin layers over Si substrates for chip commercialisation. On the other hand, quartz-based devices have hitherto been micromachined from massive crystals^{[1]}. This has the drawbacks of not being able to reduce their size below a thickness of 10 μm, and of requiring bonding the quartz crystals onto silicon substrates^{[2]}, for most applications thereof. These drawbacks represent high stresses for the microelectronics industry, because the demand on thinner single-crystal quartz wafers is currently high to enable the use of devices with higher working frequencies, as well as for their ability to reach lower detection levels with a better sensitivity^{[3]}.

Quartz α is a strategic material in Europe, widely used as a piezoelectric material because of its exceptional properties. Indeed, quartz-α has an excellent thermal and chemical stability and high mechanical properties, which makes it one of the best candidates for frequency control devices and acoustic and mass sensor technologies. The scientific publication by Carretero-Genevrier, A. et al. (“Soft-Chemistry-Based Routes to Epitaxial Alpha-Quartz Thin Films with Tunable Textures”) in Science 340, 827-831 (2013)^{[4]} describes the direct chemical integration of epitaxial quartz-α on silicon substrates (100), on which the international application WO 2014/016506^{[5]} is based. In particular, this application teaches how the adaptation of the structure of the quartz-α thin layers over silicon substrates has been carried out by chemical deposition in solution (dip-coating technique, generally designated by a person skilled in the art by the English terms “dip-coating”), which has allowed controlling the texture, the density and the thickness of the thin layers.

However, the quartz-α thin layers obtained by this technology cannot be used to make piezoelectric microelectromechanical systems (MEMS).

Consequently, there is a considerable interest in developing an industrialisable technology for manufacturing a microelectromechanical system in the form of a piezoelectric resonant membrane comprising a piezoelectric epitaxial pseudo-substrate based on an epitaxial quartz-α layer over a silicon wafer, such a microelectromechanical system having micrometric dimensions and being for example intended to make sensors.

### DESCRIPTION OF THE INVENTION

To this end, the Applicant has developed a microelectromechanical system in the form of a piezoelectric resonant membrane comprising:
a piezoelectric epitaxial pseudo-substrate comprising a silicon wafer (100) having a back face and a front face, and an epitaxial quartz-α thin layer (100) over said front face (21) of said wafer; and
a stack of three successive layers of SiN, SiO₂ and SiN deposited over said back face of said wafer, and
at least one opening passing through said stack and partially said silicon wafer (100) to a depth p1 starting from said front face of the wafer, said opening defining an unprotected area of silicon (100) in a plane parallel to said wafer located at the depth p1 inside said wafer.

By “thin film”, it should be understood a coating whose thickness could vary from a few atomic layers to ten micrometres, for example from 2 angstroms to 20 μm, for example from 100 nm to 2 μm. For example, this may consist of a thin layer as described in S. KUMAR, Dr. D. K. ASWAL, Recent Advances in Thin Films. Materials Horizons: From Nature to Nanomaterials. Springer, Singapore. https://doi.org/10.1007/978-981-15-6116-0_1^{[6]}. For example, when deposited over a substrate, for example a silicon wafer, this coating could modify the properties of said substrate over which it is deposited.

By “epitaxial quartz-α” over said silicon wafer, it should be understood a growth of the quartz-α oriented with respect to a substrate, for example a silicon wafer, for example monocrystalline, having elements of common symmetry in their crystal lattices, for example a lattice match or a lattice number. For example, it may consist of quartz-α epitaxially grown with respect to a substrate, for example a silicon wafer, obtained by epitaxy, for example by hetero-epitaxy. For example, it may consist of a hetero-epitaxy, in which the quartz-α and the silicon are crystals with different chemical natures.

By “epitaxial quartz-α thin film”, it should be understood an epitaxial quartz-α layer at the surface of a substrate, for example a silicon wafer, whose thickness may be comprised between from 100 nm and 2 μm. For example, it may consist of an epitaxial quartz-α layer obtained by coherent growth of said quartz-α. Advantageously, the epitaxial quartz-α thin film may be lattice-matched to said substrate, for example a silicon wafer.

By “epitaxial pseudo-substrate”, it should be understood a pseudo-substrate comprising a coherent interface at a common surface between a substrate, for example a silicon wafer, and a quartz-α thin layer forming it. By “epitaxial pseudo-substrate”, it should be understood epitaxial crystalline buffer layers over a structurally different substrate. Advantageously, these epitaxial layers, also so-called metamorphic buffer layers, may offer a solution to the lack of native substrates for (i) developing new microelectronic technologies, (ii) extending the application space of existing devices, or even (iii) completely new technologies by stabilising material phases with inaccessible properties (cf. Ding, C. et al. Wafer-scale single crystals: crystal growth mechanisms, fabrication methods, and functional applications. J Mater Chem C 9, 7829-7851 (2021))^{[7]}.

Advantageously, the wafer may preferably have a thickness in the range of 100 microns and its faces will preferably be polished.

In other words, the thickness of the silicon wafer (100) may be from 100 to 2000 microns, for example equal to 100 microns.

In other words, at least one of the faces of the silicon wafer (100) may be polished, for example at least 2 faces, at least 3 faces, at least 4 faces, for example all of the faces of the silicon wafer (100) may be polished. For example, the front face and the back face of the silicon wafer may be polished.

Advantageously, each of the back and front faces of the wafer may have a surface area of at least 20 cm², and preferably between 20 cm² and 82 cm².

Advantageously, the quartz-α thin layer (100) may have a homogeneous crystallisation with a mosaicity around the peak (100) of quartz comprised between 6° and 1° and a thickness comprised between 100 nm and 1 μm.

Preferably, the quartz-α (100) thin layer may have a thickness comprised between 200 nm and 1 μm.

Preferably, the quartz-α thin layer may have a homogeneous crystallisation with a mosaicity comprised between 2.5° and 1.4°.

The microelectromechanical system in the form of a piezoelectric resonant membrane may have a thickness E corresponding to the sum of the thicknesses of the piezoelectric epitaxial pseudo-substrate comprising a silicon wafer (100) having a back face and a front face and an epitaxial quartz-α (100) thin layer over said front face (21) of said wafer; and of the stack of three successive layers of SiN, SiO₂ and SiN deposited over said back face of said wafer. The thickness E of the microelectromechanical system in the form of a piezoelectric resonant membrane may be comprised from 100 μm to 1 mm, for example from 200 μm to 300 μm, for example 280 μm.

According to the invention, the microelectromechanical system in the form of a piezoelectric resonant membrane may have a thickness E′ (E′=E−p1) corresponding to the difference between the thickness E and the depth p1.

In other words, the microelectromechanical system in the form of a piezoelectric resonant membrane may have a thickness E′ at the opening defining an unprotected area of silicon (100).

The thickness E′ may be comprised between 1 μm and 50 μm, for example from 2 μm to 13 μm, for example equal to 2 μm.

According to an advantageous embodiment of the microelectromechanical system according to the invention, the unprotected area of silicon (100) of the opening may have a square shape, for example with a side of 1 mm, 2.5 mm, 3 mm, 3.5 mm and 4 mm, at the depth p1.

In other words, the unprotected area of silicon (100) of the opening at the depth p1 may have a surface area comprised from 1 mm² to 16 mm², for example 6.25 mm², 9 mm², 12.25 mm².

Preferably, the microelectromechanical system according to this advantageous embodiment may comprise 4 straight side walls, substantially perpendicular to the wafer to a given depth p2 located under the depth p1 starting from the front face and inside the wafer, the side walls being extended by 4 inclined walls with a trapezoidal shape and forming an angle α of 54.7° with respect to a plane parallel to the wafer located at the depth p2, so as to delimit in a recessed manner the contours of a hollow truncated pyramid.

Advantageously, the microelectromechanical system according to the invention may further comprise a first gold layer arranged over the quartz-α (100) thin layer and a second gold layer (6) arranged over the unprotected area of silicon (100).

Advantageously, the microelectromechanical system according to the invention may further comprise an epitaxial thin layer based on ZnO or Al₂O₃ or HfO₂ microcrystals with the crystalline orientation (110) over said quartz-α (100) thin layer (3).

According to one embodiment, the microelectromechanical system according to the invention may comprise a quartz-α thin layer having an epitaxial back face over said front face of said silicon wafer and a front face in contact with a gas and/or a liquid.

The gas may herein be any gas known to a person skilled in the art. For example, it may consist of dioxygen (O₂), carbon dioxide (CO₂), nitrogen dioxide (NO₂), methane (CH₄), nitrous oxide (NO) or any mixture thereof. For example, it may consist of atmospheric air comprising 78.087% of dinitrogen (N₂), 20.95% of dioxygen (O₂), with 0.93% of argon (Ar), with 0.041% of carbon dioxide (CO₂).

The liquid may herein be any liquid known to a person skilled in the art. For example, it may consist of a biological liquid, for example blood, cerebrospinal fluid, urine, saliva or any mixture thereof. For example, it may consist of a cell culture medium. For example, it may consist of a commercially-available cell culture medium, for example a culture medium comprising a saline solution in a Dulbecco phosphate buffer (DPBS) with a pH comprised between 7.0 and 7.3 commercialised by the company Thermofischer scientific. For example, it may consist of a cell culture medium comprising bovine serum albumin (BSA), for example a 1× saline buffer solution comprising 1% BSA, with a pH comprised between 5 and 7. For example, it may consist of a cell culture medium comprising 10% fœtal bovine serum, 1% Penicillin Streptomycin and HEPES, for example a commercially-available cell culture medium, for example the Iscove's Modified Dulbecco's Medium (IMDM) commercialised by the company Thermofischer scientific. It may consist of an aqueous, oily solution or an emulsion. For example, it may consist of water, preferably ultrapure water, for example ultrapure water with a resistivity comprised between 18 and 19 MΩ·cm, for example equal to 18.2 MΩ·cm.

Said front face of the quartz-α thin layer may herein be partially or entirely in contact with the gas and/or the liquid. For example, when the quartz-α thin layer is entirely in contact with the gas and/or the liquid, the percentage of the surface area of the front face of the quartz-α thin layer in contact with the gas and/or the liquid is 100%.

The surface of the front face of the quartz-α thin layer in contact with the gas and/or the liquid may be located parallel to said unprotected area of silicon (100) of the opening at the depth p1.

The surface area of the front face of the quartz-α thin layer in contact with the gas and/or the liquid may be identical to or different from the surface area of the unprotected area of silicon (100) of the opening at the depth p1. For example, the surface of the front face of the quartz-α thin layer in contact with the gas and/or the liquid may be comprised from 1 mm² to 16 mm², for example 6.25 mm², 9 mm², 12.25 mm².

The shape of the surface of the front face of the quartz-α thin layer in contact with the gas and/or the liquid may be a square, circular shape.

The gas and/or liquid may herein be contained in a tank comprising at least one opening placed in contact with the front face of the quartz-α thin layer.

The tank may have a shape selected from among a cubic shape, a parallelepiped shape, a domed shape. For example, the tank may be cubic shaped.

The tank may be deformable or rigid.

The tank may consist of any suitable material known to a person skilled in the art. For example, it may consist of a material selected from the group comprising silicone, polydimethylsyloxane (PDMS). For example, the material may be silicone.

The tank may comprise a volume of gas and/or liquid comprised from 60 μL to 160 μL, for example from 80 μL to 140 μL.

For example, the volume of the tank may be 352.8 mm³.

The tank may be completely or partially filled with the gas and/or the liquid.

The tank may further comprise at least one inlet opening for the gas and/or the liquid of the tank.

The tank may further comprise at least one outlet opening for the gas and/or the liquid of the tank.

Another object of the present invention is a method for manufacturing a microelectromechanical system according to the invention as described hereinabove, said method then comprising the following steps:
A) a step of providing or manufacturing a piezoelectric epitaxial pseudo-substrate as defined hereinabove, i.e. comprising a silicon wafer (100) having a back face and a front face and an epitaxial quartz-α thin layer (100) over the front face of the wafer;
B) a step of depositing a stack of three successive layers of SiN, SiO₂ and SiN over the back face of the wafer,
C) a step of pre-etching said stack by a physical dry etching process to form at least one cavity therein; then
D) a chemical etching step (for example an acidic chemical etching using TMAH (tetramethylammonium hydroxide) or basic using KOH) to form at least one opening in the silicon wafer (100) starting from said at least one cavity, said opening defining an unprotected area of silicon (100) in a plane parallel to the wafer that is located at the depth p1 inside the wafer.

According to a first embodiment of the method according to the invention, step C) of pre-etching the stack may consist of laser etching, and in this case, the method according to this first embodiment may further comprise:
between step C) and step D), a step C′) of laser etching (for example with a femto-laser) the wafer to a depth p2 in the wafer which is located between the depth p1 and said stack, to dig, starting from said cavity, 4 straight side walls substantially perpendicular to said wafer to the depth p2; and
a step C″) of protecting the quartz-α (100) thin layer;
step D) of extending, starting from the depth p2, the chemical etching to the depth p1, the straight side walls by 4 inclined walls with a trapezoidal shape and forming an angle α of 54.7° with respect to a plane parallel to the wafer located at the depth p2, so as to delimited in a recessed manner the contours of a hollow truncated pyramid.

In this first embodiment, the laser will be used at a frequency of 57 MHZ with a diameter of 15 μm, and/or a power of 2 W.

According to a second embodiment of the method according to the invention, step C) of pre-etching said stack may consist of a Reactive-Ion Etching (generally known by the English acronym RIE, standing for “Reactive Ion Etching”), said method then further comprising, between step B) and step C), the following steps:
a step B1) of protecting the back face of said stack by depositing a negative resin layer; followed
by depositing B2) over said negative resin layer a photolithography mask comprising at least one orifice, then
exposing B3) the set to UV radiations (for example, for 5 s with 37.5 mj·cm⁻²) and annealing;
immersing B4) in a negative developer bath, to form at least one cavity in said negative resin layer;
   wherein step C) of etching by Reactive-Ion Etching is intended to extend etching of said cavity in said stack, so as to form 4 straight side walls therein; and
   wherein the chemical etching step D) extends, starting from said cavity, the chemical etching to the depth p1, said straight side walls being extended by 4 inclined walls with a trapezoidal shape and forming an angle α of 54.7° with respect to said wafer.

Advantageously, for both of these two embodiments of the method according to the invention, a piezoelectric epitaxial pseudo-substrate will be used which could be manufactured as follows:
A1) a step of preparing a composition comprising a solvent, at least one silica precursor and/or colloidal silica, and a catalyst selected from among the following elements with the oxidation degree +2 forming the group comprising strontium, barium, calcium, magnesium and beryllium or from among the following elements with the oxidation degree +1 forming the group comprising cesium, rubidium, lithium, sodium or potassium, said catalyst being present at a catalyst: SiO₂ molar ratio comprised between 0.0375 and 0.125, and preferably comprised between 0.075 and 0.125, and still better in the range of 0.1;
A2) a step of providing a silicon wafer (100) having a back face and a front face, the wafer 2 could be made of N-doped silicon and having a resistivity in the range of 0.025 Ohm/cm² and each of the front and back faces could have a surface area of at least 20 cm², and preferably comprised between 20 cm² and 82 cm²;
A3) a step of depositing by spin-coating at least one layer of the composition obtained upon completion of step A1), the deposition being carried out over at least one portion of said back face of said wafer; then
A4) a step of heat pretreatment at a temperature comprised between 400° C. and 600° C., to form, upon completion of step C′), a thin layer of consolidated amorphous silica (3), steps A3) and A4) could be reiterated successively once or several times, and advantageously four times;
A5) a step of heat treating said consolidated amorphous silica thin film at a temperature comprised between 800° C. and 1,200° C.

Advantageously, the composition prepared in step A1) could further comprise a non-ionic surfactant, such as polyoxyethylene cetyl ether.

Preferably, the composition prepared in step A1) could comprise a precursor selected from among methyltrimethoxysilane (MTMS), tetraethoxysilane (TEOS), methyltriethoxysilane (MTES), dimethyl-dimethoxysilane, and mixtures thereof, and preferably tetraethoxysilane (TEOS).

Advantageously, the step A3) of deposition by spin-coating could comprise:
a first phase of dynamic distribution of the composition of step A1) by centrifugation at a speed of 100-500 rpm, for 5 to 10 seconds; followed by;
a second phase of forming the quartz-α (100) thin film by centrifugation at a rate of 500-6,000 rpm, for 10 to 40 seconds, the two distribution phases being separated by a standby time which could be comprised between 0 and 15 s.

Preferably, the heat treatment step A5) could be carried out at 980° C. for a duration of 5 hours, in a tubular furnace with an air flow of 12 L/min.

For this second embodiment, step B) of the method according to the invention could be carried out by plasma-enhanced chemical vapour deposition (generally designated by the English acronym PECVD), preferably at 280° C.

### BRIEF DESCRIPTION OF THE DRAWINGS

The following examples illustrate the invention, in connection with the figures commented hereinbelow, yet without limiting its scope:

FIG. 1 schematically shows the various steps of the method for manufacturing a microelectromechanical system in accordance with the first embodiment;

FIG. 2 illustrates in particular step D) of chemical etching (using TMAH) using a protection system;

FIG. 3 illustrates the impact of laser etching during the method for manufacturing a microelectromechanical system in accordance with the first embodiment (so-called hybrid etching), combining laser etching and chemical etching:

FIG. 3a shows in particular the comparison of the obtained etching depths as a function of the power of the laser and the number of passages thereof, the comparison being carried out using a profilometer;

FIG. 3b shows in particular the comparison of the obtained etching depths as a function of the power of the laser and the number of passages thereof, the comparison being carried out by optical microscopy (this method having the same accuracy as that one used in FIG. 3a);

FIG. 3c shows images obtained using a profilometer by laser etching optical microscope at a fixed power 2W with variation in the number of passages of the laser: the obtained optical images are 3D representations of the different cavities. 6 passages allow obtaining 100 μm, 7 passages 115 μm, 8 passages 132 μm and 10 passages 160 μm;

FIG. 3d illustrates the combination of laser etching with chemical etching by TMAH heated to 84° C. in a water bath: etching kinetics for 3h30 of attack is 0.8 μm/min;

FIG. 3e comprises SEM images of the surface condition before and after the TMAH attack (an improvement in the surface condition of the etched area thanks to the chemical attack is noticed: top), as well as a profilometer of the depth obtained after laser etching coupled with chemical etching by TMAH for 3h30, the obtained final depth is 286 μm);

FIG. 4 is a diagram allowing calculating the width of the opening d in order to obtain a membrane with the desired width;

FIG. 5 schematically shows the different steps of the method for manufacturing a microelectromechanical system in accordance with the second embodiment;

FIG. 6 illustrates in particular etching of silicon by chemical etching by TMAH heated to 84° C., and comprises:

FIG. 6a shows the evolution of the silicon etching depth over time;

FIG. 6b shows the evolution of the kinetics of Si(100) etching by TMAH over time;

FIG. 6c is an optical profilometer of a 3D representation of the cavity created by etching showing that a depth of 90 μm is made on a substrate made of Si(100) with a 100 μm thickness;

FIG. 7 illustrates the characterisation of a quartz-α layer carried out under “optimum” conditions on a Si wafer with a diameter of 2 inches:

FIG. 7a comprises an optical image showing the continuity of the quartz-α thin layer (to the right) and an SEM image showing the thickness of the crystallised quartz-α layer (to the left);

FIG. 7b is an AFM image showing the texture and the roughness of the quartz-α thin layer;

FIG. 7c shows the θ-2θ diffraction results, with an inset consisting of a mapping of the mosaicity grade of the wafer around the peak (100);

FIG. 7d is a pole figure showing the epitaxy between the Si wafer and the quartz-α layer.

FIG. 8 shows a microelectromechanical system in the form of a piezoelectric resonant membrane according to the invention on a substrate of 100 μm:

FIG. 8a is an image of the 3-inch wafer before (left photo) and after (right photo) the crystallisation;

FIG. 8b shows microscope images comprising an SEM image (to the left) and a 3D representation of the etching carried out during the chemical etching by TMAH;

FIG. 8c shows an analysis of the quartz membrane by X-ray diffraction carried out upon completion of the method for making the membrane (c1, at the top to the right) and a 2D diffractogram of the quartz layer of the membrane and a rocking curve (“Rocking curve”) of the quartz next to the membrane showing a degree of mosaicity of 1.67° (at the bottom);

FIG. 8d shows a 3D diagram of the microelectromechanical system according to the invention;

FIG. 9 illustrates the characterisation by laser vibrometry of the piezoelectric membrane made of α-quartz(100)/Si(100):

FIG. 9a is a laser vibrometry revealing a resonance frequency of 54.25 kHz and a quality factor of 1,346 in air;

FIG. 9b comprises a mapping of the amplitude movement (pm) of the piezoelectric membrane excited by an electric current at the frequency of different mechanical modes of the piezoelectric membrane at f=54.25 kHz and at the different harmonics at f=88.7 kHz, f=128.6 kHz and f=198.1 kHz.

FIG. 10 shows a graph (FIG. 10A) representing the evolution of the resonance frequency in kHz (abscissa) and of the maximum deformation of the piezoelectric membrane as a function of its thickness and of its surface in mm² (ordinate). FIG. 10B shows the photograph of a substrate including 2.5×2.5 mm, 3×3 mm, 3.5×3.5 mm and 4×4 mm (to the left) membranes.

FIG. 11 shows photographs (FIG. 11A) of a microelectromechanical system comprising a quartz-α thin layer whose front face is in contact with a silicone-made tank of 352.8 mm³. FIG. 11B shows a graph of the evolution of the resonance frequency in kHz (abscissa) of the piezoelectric membrane as a function of its surface in mm² (ordinate) when the back face of the quartz-α layer of said membrane is in contact with air or with a tank comprising water.

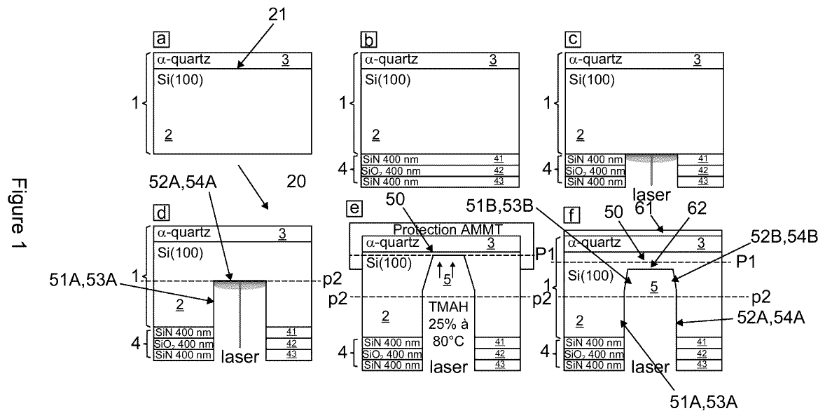

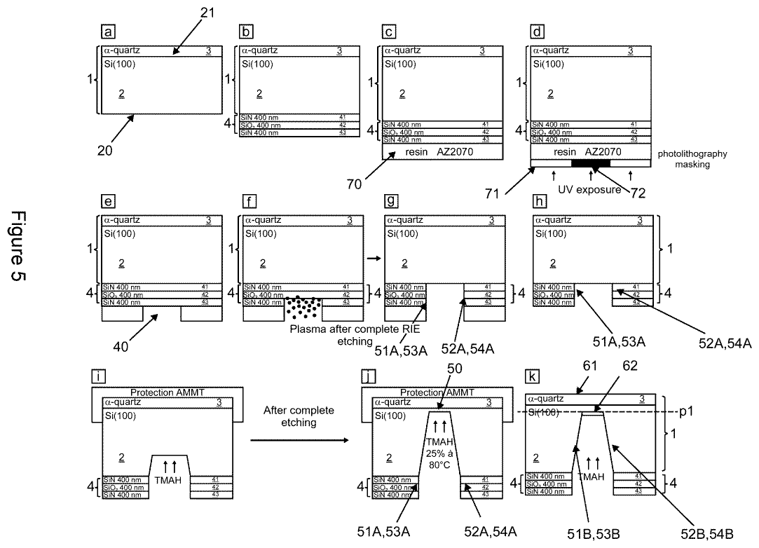

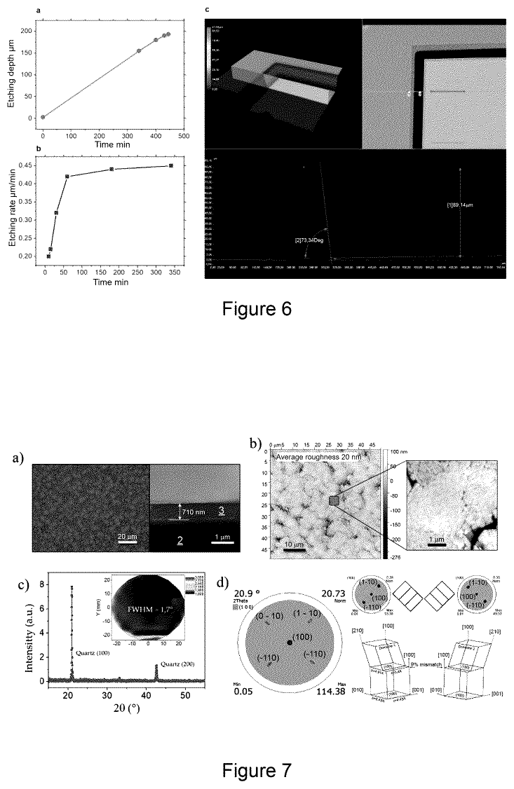

FIGS. 1 to 6 are described in the previous descriptive part of the invention (detailed description of the figures), whereas FIGS. 7 to 11 are described in more detail in the following examples, which illustrate the invention without limiting its scope.

### DETAILED DESCRIPTION OF THE FIGURES

FIG. 1 schematically shows the different steps of the method for manufacturing a microelectromechanical system in accordance with the first embodiment:

### Step A (FIG. 1a):

The first step is a step of providing or manufacturing a piezoelectric epitaxial pseudo-substrate 1 comprising a silicon (100) wafer 2 having a back face 20 and a front face 21, and an epitaxial quartz-α (100) thin layer 3 over the front face 21 of the wafer 2.
Then, it is proceeded with the complete cleaning of the quartz(100)/Si(100) substrate with acetone, ethanol and isopropyl alcohol (IPA) in order to remove any impurity that might pollute the material or alter the microfabrication process;

### Step B (FIG. 1b):

Afterwards, the deposition of a stack 4 of three successive layers of SiN 41, SiO₂ 42 and SiN 43 over the back face 20 of the wafer 2 is carried out;
this deposition preferably consisting of a plasma-enhanced chemical vapour deposition (PECVD) at 280° C.;
the stack comprises 400 nm of SiN at 280° C., 400 nm of SiO₂ at 280° C. and 400 nm of SiN at 280° C. on Si(100).
It is very important to comply with the order of deposition of these layers as well as their deposition temperature and thickness;

### Step C (FIG. 1c):

This consists of a step of pre-etching the stack 4 by laser to form at least one cavity 40 therein, this step allowing drawing the desired geometries for the future membrane and reducing the final chemical attack time. The desired etching depth is to be defined according to the energy of the used laser;

### Step C′ (FIG. 1d):

This consists of a step of laser etching of the wafer 2 to a depth p2 in the wafer 2 which is located between the depth p1 and the stack 4, to dig, starting from the cavity 40, 4 straight side walls 51A, 52A, 53A, 54A substantially perpendicular to the wafer 2 to the depth p2

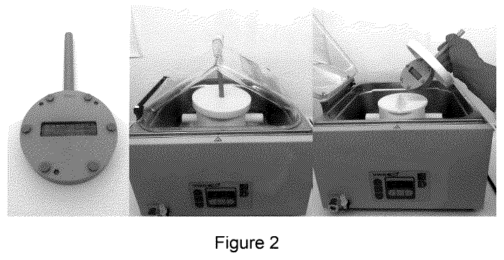

### Steps C″ and D (FIGS. 1e and 2):

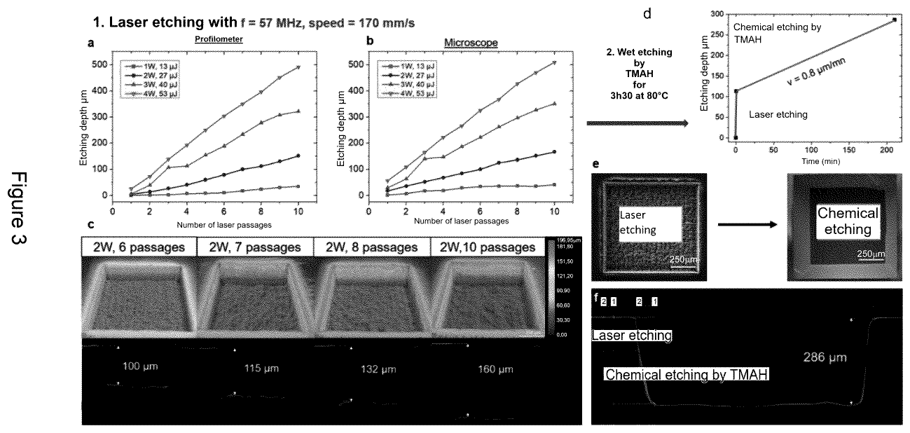

This consists, first of all, of a step of protecting (with regards to the subsequent chemical etching by TMAH) the back face of the stack 4 by deposition of a negative resin layer (for example AZ2070):
Afterwards, the set is placed in the water bath (FIG. 2). The expected etching rate is in the range of 0.8 μm/min after one hour (cf. FIG. 3). Once the desired membrane thickness has been obtained, the set should be carefully removed from the water bath;
This consists of a chemical etching step forming at least one opening 5) in the silicon (100) wafer 2 starting from the cavity 40, this opening 5) defining an unprotected area 50 of silicon (100) in a plane parallel to the wafer 2 located at the depth p1 inside the wafer 2;

### Deposition of a Gold Layer (FIG. 1f):

A deposition of a gold layer by cathode sputtering on the front face and on the back face allows making the device functional.

FIG. 3 shows the study of the impact of laser etching in the method according to the invention on the surface condition of the Si(100).

Different tests according to the power of the laser (1W-4W) as well as the number of passages thereof (between 1 and 10) on the area to be etched have been carried out.

The laser is used at a frequency of 57 MHz with a diameter of 15 μm. FIGS. 3a and 3b show the evolution of the depth of the obtained etchings as a function of these different parameters. The higher the power and the greater the number of passages, the greater the depth will be. A power of 2 Whas been selected and different etchings varying according to the number of passages of the laser have been carried out.

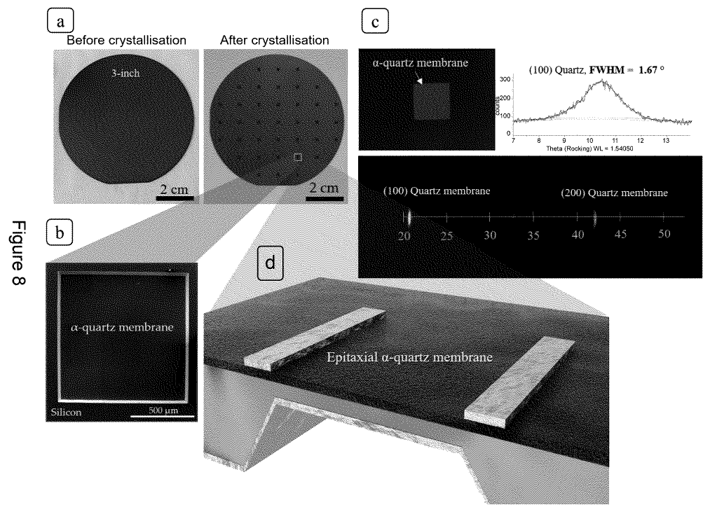

FIG. 3c shows the evolution of the etching depth. A power of 2 W allows etching 15 μm on average per passage of the laser. The advantage of this step is to be able to etch very rapidly (the duration of etching is in the range of a few seconds because the laser moves at the speed of 170 mm/s) a quite substantial depth of Si(100) without using technological means that are more complex and expensive like deep Reactive-Ion Etching (usually designated by the English acronym DRIE standing for “Deep Reactive Ion Etching”) or requiring more time like chemical etching by KOH or TMAH. However, following this laser etching, the surface condition of the future membranes is very rough, as shown by the 3D images of FIG. 3c. In order to smooth this surface and complete the etching more gently, to obtain exactly the desired depth, a chemical etching by TMAH (heated at 84° C. in a water bath) is performed. The obtained kinetics are 0.8 μm/min (FIG. 8d). The TMAH will smooth the surface condition (FIG. 8e), a feature essential to the proper mechanical operation of the membrane. A chemical attach for 3h30 etches 171 μm of Si(100) (FIG. 8f).

Hence, the combination of laser etching and of chemical etching allows improving the quality, the speed and the control of etching while ensuring a good surface condition of the membrane

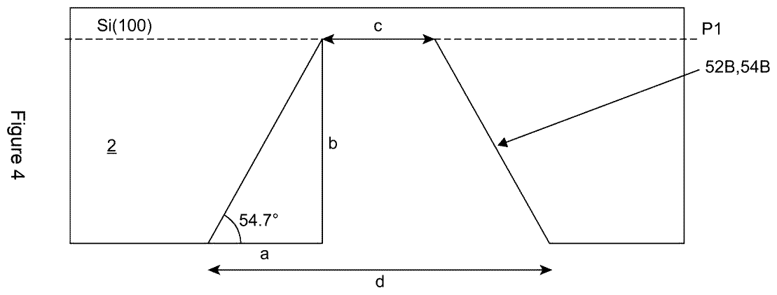

FIGS. 4 and 5 relate to the method for manufacturing a microelectromechanical system in accordance with the second embodiment, FIG. 5 schematically describing the different steps of the method for manufacturing a microelectromechanical system in accordance with the first embodiment:

### Step A (FIG. 5a):

In the same manner as for the method according to the first embodiment, the first step is a step of providing or manufacturing a piezoelectric epitaxial pseudo-substrate 1 comprising a silicon (100) wafer 2 having a back face 20 and a front face 21, and an epitaxial quartz-α (100) thin layer 3 over the front face 21 of the wafer 2.
Then, it is proceeded with the complete cleaning of the quartz(100)/Si(100) substrate with acetone, ethanol and IPA in order to remove any impurity that might pollute the material or alter the microfabrication process;
   Step B (FIG. 5b): Identical to that of the Method According to the First Embodiment (Illustrated in FIG. 1b).
It is then proceeded with a prior dehumidification of the substrate 1 at 115° C. for 5 minutes;

### Step B1 (FIG. 5c):

A protection of the back face of the stack 4 is carried out by depositing a negative resin layer 70 (for example a negative resin commercialised under the brand name AZ2070), this deposition could, for example, be carried out by centrifugation at 4,000 rpm for 30 seconds. Afterwards, the set is placed over a hot plate at 115° C. for 1 minute.

### Step B2 (FIG. 5d):

It is proceeded with the deposition of a photolithography mask 71 comprising at least one orifice 72 over the negative resin layer 70. This photolithography mask should be drawn, and then made upstream. This mask includes one single masking level with different squares of variable sizes, corresponding to the future membranes. The size of the squares should be calculated according to the size of the desired membranes but also according to the depth of etching to be carried out. Indeed, this chemical etching is performed on Si(100), it therefore follows the crystalline plane of the silicon, thereby creating an etching with an angle of 54.7°. Depending on the thickness of the substrate, a sufficiently large opening d capable of passing throughout this thickness b with this angle should be provided for. A rapid trigonometric calculation allows finding the necessary lengths (cf. FIG. 4)
Afterwards, the photolithography mask is placed over the resin at the selected location.

### Steps B3 and B4 (FIG. 5e):

Exposure to UV is carried out for 5 seconds with a dose of 37.5 mJ·cm⁻². Afterwards, annealing is applied for 1 minute at 115° C.
Then, the set is immersed for 1 minute in a negative developer bath (for example the negative developer MIF 726), to form, in the negative resin layer 70, the cavities 40 corresponding to the squares located on the photolithography mask. Afterwards, a vitrification of the resin 70 is done by placing the substrate 1 over a hot plate at 125° C. for 5 minutes.

### Step C (FIGS. 5f to 5h)

It is proceeded with the dry etching step C) consisting of a Reactive-Ion Etching, in order to remove the protective layer at the various locations revealed by the photolithography step (5f).
The SiN/SiO₂/SiN alternation is removed by a gas mixture of 60 sccm CHF₃, 20 sccm O2, and 10 sccm Ar ionised at 100 W. This step allows reaching the Si(100) which will be etched (5g) later on.
Finally, the excess resin should be removed thanks to an oxygen plasma for 10 minutes with 90 sccm of O₂. Afterwards, a complete cleaning is carried out with acetone, ethanol and IPA (5h).

### Step D (FIGS. 5i to 5k)

It is proceed with step D) as follows:
   the pseudo-substrate is placed in a carrier adapted to its morphology by the company AMMT (FIGS. 5i and 2), the face with the quartz being oriented inwards;
   afterwards, the set is placed in the water bath. The expected etching rate is 0.4 μm/min after one hour (cf. FIG. 5). Once the desired membrane thickness is obtained (FIG. 5j), the set should be removed carefully from the water bath.
Finally, a deposition of a gold layer by cathode sputtering on the front face and on the back face allows making the functional device (5k).

### EXAMPLES

The nature of the products used for the manufacture of microelectromechanical systems according to the invention based on piezoelectric epitaxial pseudo-substrates, the method implemented for manufacture thereof and optimisation of its operating conditions, as well as the characterisation methods are detailed hereinafter.

### Products, Raw Materials:

Wafers (or “wafer”) of N-doped silicon: wafers in the form of a standard disk of 2, 3 and 4 inches (i.e. respectively with a diameter of 5.08 cm, 7.62 cm and 10.16 cm) are used,
tetraethoxyorthosilane (TEOS) at 98%, commercialised by the company Sigma-Aldrich,
ethanol (EtOH),
ultra-pure H₂O.
hydrochloric acid (HCl) at 37%, commercialised by the company Sigma-Aldrich,
strontium chloride (SrCl₂·6H₂O), commercialised by the company Sigma-Aldrich,
monohexadecylether commercialised under the brand name Brij-58® by the company Sigma-Aldrich,
solution of TMAH at 25%;
negative resin commercialised under the brand name AZ2070 commercialised by the company Microchemicals;
negative developer bath MIF 72 commercialised by the company Microchemicals;

### Devices for Making and for Structural and Microstructural Characterisation

LPKF Protoplaste U4
optical microscopy and atomic force microscopy (AFM: English acronym standing for “atomic force microscope” commercialised under the brand name MULTIMODE by the company Veeco), to determine the roughness and the appearance of the quartz-α layer (100);
optical microscopy using an optical microscopy of the brand name KEYENCE;
field-emission scanning electron microscopy (SEM or SEM-FEG standing for scanning Electron Microscopy-Field Emission in English) commercialised under the brand name SU90 by the company Hitachi, to determine the thickness of the quartz-α layer (100);
diffractometer commercialised under the brand name GADDS D8 in a Bruker setup, Copper irradiation 1.54056 Å, to determine the epitaxy, the mosaicity and the crystalline homogeneity;
the profilometer commercialised by the company Veeco

### Example 1: Making of an Example of a Piezoelectric Epitaxial Pseudo-Substrate According to the Invention

In accordance with step A) of the method according to the invention, a solution of precursors having the following initial composition (in moles) is prepared:

### TEOS: Brij-58:HCl:EtOH:SrCl2:1:0.3:0.7:25:0.1.

A 3-inch silicon wafer having a thickness of 100 μm, with a conductivity of 0.025 Ω/cm is used.

Then, in accordance with step C) of the method according to the invention, the precursor composition prepared during step A) is deposited over one of the faces 20 of this wafer 2. The deposition is carried out by spin-coating at a temperature of 20° C. and 40% relative humidity, under the following conditions:
i. a dynamic distribution of 1 mL of solution at 300 rpm, for 5 s;
ii. then, a final rotation of 2,000 rpm for 30 seconds.

In accordance with step C′) of the method according to the invention, the layer with a composition thus deposited by a heat treatment at 450° C. is consolidated to obtain a consolidated amorphous silica thin layer, which forms a precursor thin layer of the quartz α thin layer (100).

The succession of these steps C) and C′) is repeated 4 times.

Then, it is proceeded with the final heat treatment of step D), of the silicon wafer thus coated with amorphous silica, at a temperature of 980° C. for 5 hours in a tubular furnace with an air flow of 12 L/min. Afterwards, the furnace is turned off and let to cool down naturally to 25° C.

Upon completion of step D) of the method according to the invention, a silicon wafer (or “wafer”) (100) covered with a quartz-α layer is obtained. A silicon wafer (or “wafer”) (100) covered with a quartz-α layer has been obtained, which has been characterised as follows (cf. FIG. 7):
FIG. 7a (located on the right) shows that the quartz-α thin layer thus obtained consists of crystalline domains of quartz-α percolated by forming a homogeneous and continuous mattress;
FIG. 7a (located on the left) shows the section of the quartz-α layer, which has a thickness of 710 nm;
FIG. 7b (AFM image) shows the texture and roughness of the surface of the layer with an average roughness of 10 nm, measured over a surface area of 50×50 μm;
FIG. 7c shows that the crystallised layer is actually a quartz-α monocrystalline layer. The mapping that has been carried out shows a mosaicity of 1.7° which is homogeneous throughout the Si wafer, for the peak (100) of the quartz-α;
FIG. 7d shows the results of the study of the epitaxy by X-ray diffraction (XRD), and in particular an epitaxy relationship of the quartz layer (100) over the silicon substrate (100) throughout the polar figure around the reflection (100)=20.9°. FIG. 7d also shows the presence of two quartz domains perpendicular to one another. These two domains which have an identical epitaxy relationship with the silicon substrate ([210] α-quartz(100)/[100] Si (100) are enabled by the cubic symmetry of the silicon substrate. Finally, FIG. 7d shows a 3D representation model of the orientation and of the relationship of the two crystalline domains of the epitaxial quartz dense layer on silicon.
FIG. 7d also shows the existence of two perpendicular crystal domains of quartz with the same epitaxial relationship with silicon. The existence of these two crystalline domains of the quartz layer is possible thanks to the cubic symmetry of the silicon substrate.

### Example 2: Making of Piezoelectric Microelectromechanical Systems Starting from Piezoelectric Epitaxial Pseudo-Substrates According to the Invention

Piezoelectric epitaxial pseudo-substrates according to the invention are prepared in accordance with the previous example.

Then, starting from these piezoelectric epitaxial pseudo-substrates, it is proceeded with the microfabrication of 25 piezoelectric membranes in accordance with the second embodiment of the method according to the invention, by chemical etching using the 25% TMAH solution. This etching has been carried out for 3h45, which is the time required to etch about 95 μm of Si(100).

FIG. 8 shows the completion of the entire process. FIG. 8a shows the 3-inch wafer before (left) and after (right) crystallisation. The microscope images of FIG. 8b are respectively the SEM image and the 3D representation of the etching carried out during the chemical attack by TMAH.

FIG. 8c shows the structural characterisation of a piezoelectric membrane through the micro-diffraction technique. The mosaicity values of the membrane show that the microfabrication process has not damaged the crystalline quality of the a layer.

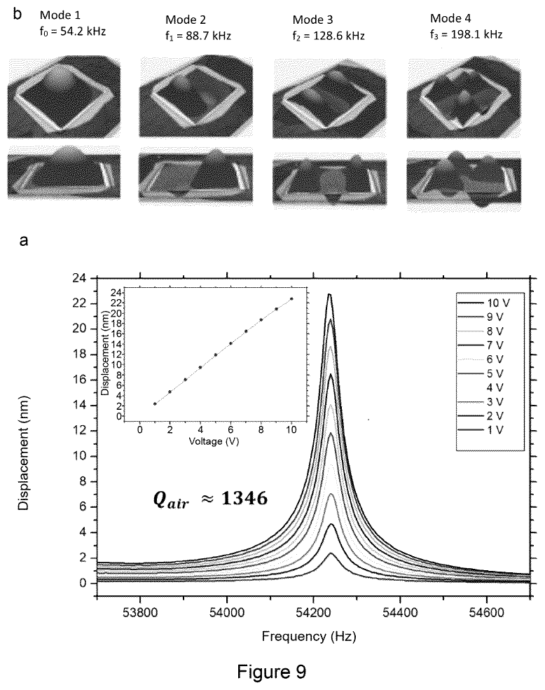

Afterwards, a characterisation by laser vibrometry (cf. FIG. 9) has been performed in order to determine the mechanical performances of the α-quartz(100)/Si(100) piezoelectric membrane. A frequency scan has been carried out in order to find the resonance frequency of the structure, i.e. the frequency at which the piezoelectric membrane has the highest oscillation amplitude. A resonance frequency of 54.25 kHz has been found (9a) for a 1.1 mm² membrane. Also, the amplitude of the vibrations is proportional to the injected current amplitude, which confirms the piezoelectric nature of the membrane. A quality factor of 1,346 has been calculated in ambient air. A mapping of the membrane at its resonance frequency (9b) has allowed noticing the mechanical movement of the latter, which movement correspond to the intended one. Then the other 3 resonance modes have been visualised at the harmonics respectively f=88.7 kHz, f=128.7 kHz and f=196.4 kHz (FIG. 13c).

These results are the proof of a consistent mechanical behaviour for a piezoelectric membrane of epitaxial quartz on silicon with an exceptionally high quality factor, which makes this piezoelectric membrane very attractive for numerous applications (for example biomedical applications in gas sensors, or to make very accurate mass balances).

### Example 3: Accurate Control of the Resonance Frequency of the Piezoelectric Membranes Made of α-Quartz Through the Control of the Size and their Thickness

The resonance frequency and the displacement of the piezoelectric membranes made of α-quartz depends on their surface and their thickness. Controlling these two morphological parameters allows accurately controlling the resonance frequency and adapting the morphology of the membrane to the frequency range of the targeted application.

Several piezoelectric membranes based on quartz of different dimensions have been made, in accordance with Example 2. These membranes are squares with a side of 2 mm, 2.5 mm, 3 mm, 3.5 mm and 4 mm. Each of these membranes are made in two series, a series with a thickness of 2 μm and a series with a thickness of 13 μm.

In other words, the thicknesses of 2 and 13 μm correspond to the thickness E′ of the microelectromechanical system in the form of a piezoelectric resonant membrane at the level of the opening defining an unprotected area of silicon (100).

This study proves a control of the size and of the thickness of the membranes. It highlights the impact of these parameters on the resonance frequency and the maximum amplitude of the devices. An increase in the surface area of the membranes reduces the value of the resonance frequency but increases its maximum displacement. For a thickness of 2 μm, a 4 mm² membrane resonates at a frequency of 10.66 kHz with a displacement of 1.5 nm while a 16 mm² membrane resonates at 3.35 kHz with a displacement of 36.35 nm.

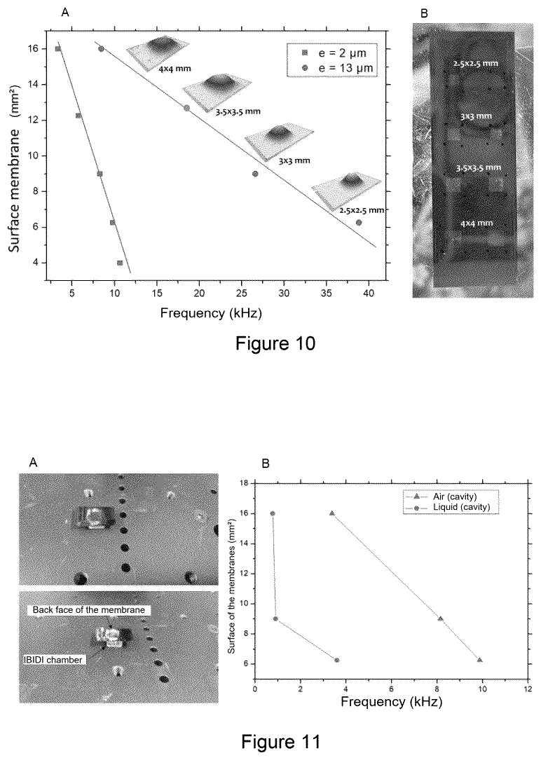

The results of the experimental data comprising the resonance frequency fᵣ and the maximum displacement for each membrane with a surface area of 4, 6.25, 9, 12.25, 16 mm² and thickness of 2 and 13 μm, are reported in Table 1 hereinafter. FIG. 10 also shows that a thinner membrane will resonate at a lower frequency than a thicker membrane. Two membranes have a surface area of 9 mm²: that one whose thickness is 2 μm resonates at fᵣ=8.16 kHz with a displacement Dₘₐₓ of 16.58 nm, while that one whose thickness is 13 μm resonates at fᵣ=26.55 kHz with a displacement Dₘₐₓ of 6.6 nm. In addition, a membrane with a thickness of 13 μm scans a wider range of frequencies than a membrane with a thickness of 2 μm.

This example shows that it is possible to carry out an accurate control of the resonance frequency of the piezoelectric membranes made of α-quartz based on the control of the size and of their thickness.

The results clearly demonstrate that piezoelectric membranes made of α-quartz having a thickness of 2 μm could advantageously be useful for gas detection, advantageously by photoacoustic effect, for example as described in Trzpil, W. et al. Analytic Optimisation of Cantilevers for Photoacoustic Gas Sensor with Capacitive Transduction. Sensors 21, (2021)^{[8]}. In particular, the examples clearly demonstrate that piezoelectric membranes made of α-quartz having a thickness of 2 μm may have resonance frequencies comprised from 3 to 11 kHz enabling a gas detection.

TABLE 1

| | | 2 μm | 13 μm |
|---|---|---|---|
| 4 | mm² | fᵣ = 10.66 kHz | fᵣ = 54.25 kHz |
| | | Dₘₐₓ = ^{1.5} nm | Dₘₐₓ = 1.2 nm |
| 6.25 | mm² | fᵣ = 9.88 kHz | fᵣ = 38.95 kHz |
| | | Dₘₐₓ = ^{15.31} nm | Dₘₐₓ = 3 nm |
| 9 | mm² | fᵣ = 8.16 kHz | fᵣ = 36.55 kHz |
| | | Dₘₐₓ = ^{16.58} nm | Dₘₐₓ = 6.6 nm |
| 12.25 | mm² | fᵣ = 5.68 kHz | fᵣ = 18 kHz |
| | | Dₘₐₓ = ^{20.98} nm | Dₘₐₓ = 7.5 nm |
| 16 | mm² | fᵣ = 3.35 kHz | fᵣ = 8.66 kHz |

| | |
|---|---|
| Dₘₐₓ = 36.35 nm | Dₘₐₓ = 11.8 nm |

### Example 4: Accurate Control of the Resonance Frequency of the Piezoelectric Membranes Made of α-Quartz as a Function of the Medium in Contact with the Opening Present in Said Membrane

In this example, the used membranes correspond to the quartz-based piezoelectric membranes of different dimensions described in Example 2. They consist of square membranes with a side of 2.5 mm, 3 mm, and 4 mm, having a thickness of 2 μm.

These membranes have been carried out in two series:
a series in which the back face of the epitaxial quartz-α thin film is in contact with air, as described in Example 3; and
a series in which the membrane comprises a quartz-α thin layer whose front face is in contact with a liquid contained in a cubic shaped tank made of silicone with a volume of 352.8 mm³. Said tank comprising an opening facing the quartz-α thin layer, the surface area of the opening was 70.56 mm². The volume of the liquid contained in the reservoir was 80 μL of water.

A study of the resonance frequency as a function of the surface of a piezoelectric membrane has been carried out independently for these two series.

The results of the experimental data comprising the resonance frequency fᵣ for each membrane with a surface area of 6.25, 9 and 16 mm² in a gas, namely atmospheric air comprising 78.087% of dinitrogen (N₂), 20.95% of dioxygen (O₂), at 0.93% of argon (Ar), at 0.041% of carbon dioxide (CO₂) or a liquid, namely water, are reported in Table 2 hereinafter. Two membranes have a surface area of 9 mm²: that one in the presence of the gas, namely atmospheric air resonates at fᵣ=8.16 kHz, while that one in the presence of the liquid resonates at fᵣ=0.902 KHz.

The experimental data demonstrate that the resonance frequency decreases when the tank comprised 80 μL of water. In other words, the presence of liquid reduces the resonance frequency of the membrane.

Hence, the obtained results clearly demonstrate that the piezoelectric membrane according to the invention could be set in vibration when the front face of the quarter-α thin layer epitaxially grown from said piezoelectric membrane is brought into contact with a liquid.

Hence, the obtained results clearly demonstrate that the resonance frequency of the piezoelectric membrane according to the invention could vary depending on whether the front face of the quartz-α thin layer is in contact with a gas and/or a liquid.

Thus, this example shows that the membranes may also be used in the presence of liquid for biological or other applications, for example the detection and/or the quantification of cells possibly present in the liquid.

TABLE 2

| | | GAS (AIR) | LIQUID (WATER) |
|---|---|---|---|
| 6.25 | mm² | fᵣ = 9.88 kHz | fᵣ = 3.59 kHz |
| 9 | mm² | fᵣ = 8.16 kHz | fᵣ = 0.902 kHz |
| 16 | mm² | fᵣ = 3.35 kHz | fᵣ = 0.781 kHz |

### LIST OF THE REFERENCES

1. J. S. Danel & G. Delapierre. Quartz: a material for microdevices. Journal of Micromechanics and Microengineering 1, 187 (1991).
2. B. Imbert et al. Thin film quartz layer reported on silicon. in 1-4 (2011). doi: 10.1109/FCS.2011.5977829.
3. Brinker, C. J. & Clem, P. G. Quartz on Silicon. Science 340, 818-819 (2013).
4. Carretero-Genevrier, A. et al. Soft-Chemistry-Based Routes to Epitaxial alpha-Quartz Thin Films with Tunable Textures. Science 340, 827-831 (2013).
5. C Boissiere, A Carretero-Genevrier, M Gich, D Grosso, C Sanchez: “Process for preparing an epitaxial alpha-quartz layer on a solid substrate, material obtained and uses”, WO20140165 or EP2875172.
6. S. KUMAR, Dr. D. K. ASWAL, Recent Advances in Thin Films. Materials Horizons: From Nature to Nanomaterials. Springer, Singapore. https://doi.org/10.1007/978-981-15-6116-0_1
7. Ding, C. et al. Wafer-scale single crystals: crystal growth mechanisms, fabrication methods, and functional applications. J Mater Chem C 9, 7829-7851 (2021)
8. Trzpil, W. et al. Analytic Optimisation of Cantilevers for Photoacoustic Gas Sensor with Capacitive Transduction. Sensors 21, (2021)

1. A microelectromechanical system in the form of a piezoelectric resonant membrane comprising:
a piezoelectric epitaxial pseudo-substrate comprising a silicon wafer having a back face and a front face, and an epitaxial quartz-α thin layer over said front face of said wafer;
a stack of three successive layers of SiN, SiO₂ and SiN deposited over said back face of said wafer; and
at least one opening passing through said stack and partially said silicon wafer to a depth p1 starting from said front face of the wafer, said opening defining an unprotected area of silicon in a plane parallel to said wafer located at the depth p1 inside said wafer.

2. The microelectromechanical system according to claim 1, wherein said quartz-α thin layer has a homogeneous crystallisation with a mosaicity around the peak of quartz between 6° and 1° and a thickness between 100 nm and 1 μm.

3. The microelectromechanical system according to claim 1, wherein said quartz-α thin layer has a thickness between 200 nm and 1 μm.

4. The microelectromechanical system according to claim 1, wherein said quartz-α thin layer has a homogeneous crystallisation with a mosaicity between 2.5° and 1.4°.

5. The microelectromechanical system according to claim 1, wherein said unprotected area of silicon has a square shape at the depth p1.

6. The microelectromechanical system according to claim 5, wherein said opening comprises 4 straight side walls, substantially perpendicular to said wafer to a depth p2 located under said depth p1 starting from said front face and inside said wafer, said side walls being extended by 4 inclined walls with a trapezoidal shape and forming an angle α of 54.7° with respect to a plane parallel to said wafer located at the depth p2.

7. The microelectromechanical system according to claim 1, further comprising a first gold layer arranged over said quartz-α thin layer and a second gold layer arranged over said unprotected area of silicon.

8. The microelectromechanical system according to claim 1, further comprising an epitaxial thin layer based on ZnO or Al₂O₃ or HfO₂ microcrystals with the crystalline orientation over said quartz-α thin layer.

9. A method for manufacturing a microelectromechanical system as defined according to claim 1, comprising the following steps:
A) providing or manufacturing a piezoelectric epitaxial pseudo-substrate as defined according to claim 1;
B) depositing a stack of three successive layers of SiN, SiO₂ and SiN over said back face of said wafer;
C) pre-etching said stack by a physical dry etching process to form at least one cavity therein; and
D) chemical etching step to form at least one opening in said silicon wafer starting from said at least one cavity, said opening defining an unprotected area of silicon in a plane parallel to said wafer located at the depth p1 inside said wafer.

10. The method according to claim 9, wherein said step C) of pre-etching said stack consists of laser etching and said method further comprises:
between step C) and step D), a step C′) of laser etching said wafer to a depth p2 in said wafer which is located between the depth p1 and said stack, to dig, starting from said cavity, 4 straight side walls substantially perpendicular to said wafer to the depth p2; and
a step C″) of protecting said quartz-α thin layer;
step D) of extending, starting from the depth p2, the chemical etching to the depth p1, said straight side walls by 4 inclined walls with a trapezoidal shape and forming an angle α of 54.7° with respect to a plane parallel to said wafer located at the depth p2.

11. The method according to claim 10, wherein the laser is used in step C′) at a frequency of 57 MHZ with a diameter of 15 μm.

12. The method according to claim 10, wherein the power of the laser is 2 W.

13. The method according to claim 9, wherein said step C) of pre-etching said stack is a Reactive-Ion Etching, and said method further comprises between step B) and step C):
a step B1) of protecting the back face of said stack by depositing a negative resin layer; followed
by depositing B2) over said negative resin layer a photolithography mask comprising at least one orifice, then
exposing B3) the set to UV radiations and annealing;
immersing B4) in a negative developer bath, to form at least one cavity in said negative resin layer;
said step C) of etching by Reactive-Ion Etching intended to extend etching of said cavity in said stack, so as to form 4 straight side walls therein; and
said chemical etching step D) extending, starting from said cavity, the chemical etching to the depth p1, said straight side walls being extended by 4 inclined walls with a trapezoidal shape and forming an angle α of 54.7° with respect to said wafer.

14. The method according to claim 9, wherein step A) is carried out as follows:
A1) a step of preparing a composition comprising a solvent, at least one silica precursor and/or colloidal silica, and a catalyst selected from strontium, barium, calcium, magnesium or beryllium or from cesium, rubidium, lithium, sodium or potassium, said catalyst being present at a catalyst: SiO₂ molar ratio of 0.0375 to 0.125;
A2) a step of providing a silicon wafer having a back face and a front face;
A3) a step of depositing by spin-coating at least one layer of the composition obtained upon completion of step A, the deposition being carried out over at least one portion of said back face of said wafer; then
A4) a step of heat pre-treatment at a temperature between 400° C. and 600° C., to form upon completion of step C′) a consolidated amorphous silica thin film; and
A5) a step of heat treating said consolidated amorphous silica thin film at a temperature between 800° C. and 1,200° C.

15. The method according to claim 14, wherein the composition prepared in step A1) comprises a precursor selected from the group consisting of methyltrimethoxysilane (MTMS), tetraethoxysilane (TEOS), methyltriethoxysilane (MTES), dimethyl-dimethoxysilane, and mixtures thereof.

16. The method according to claim 14, wherein step A3) comprises:
a first phase of dynamic distribution of the composition of step A1) by centrifugation at a speed of 100-500 rpm, for 5 to 10 seconds; followed by; and
a second phase of forming the quartz-α thin film by centrifugation at a rate of 500-6,000 rpm, for 10 to 40 seconds,
the two distribution phases being separated by a standby time which could be between 0 and 15 s.

17. The method according to claim 14, wherein said steps A3) and A4) are reiterated successively once or several times.

18. The method according to claim 13, wherein step B) of depositing the SiN, SiO₂ and SiN layers forming a stack over the back face of the wafer is carried out by plasma-enhanced chemical vapour deposition.

19. The method according to claim 14, wherein the composition prepared in step A1) comprises a precursor selected from tetraethoxysilane (TEOS).

20. The method according to claim 13, wherein step B) of depositing the SiN (41), SiO₂ (42) and SiN layers forming a stack over the back face of the wafer is carried out by plasma-enhanced chemical vapour deposition at 280° C.
